(19) United States
(12) Patent Application Publication
(10) Pub. No.: US 2026/0223587 A1
(43) Pub. Date: Jul. 30, 2026

(54) COMPOSITE MATERIAL AND PREPARATION METHOD THEREOF, AND PREPARATION METHOD OF LIGHT-EMITTING DEVICE

(71) Applicant: TCL Technology Group Corporation, Huizhou, Guangdong (CN)

(72) Inventor: Donglian ZHANG, Huizhou, Guangdong (CN)

(73) Assignee: TCL Technology Group Corporation, Huizhou, Guangdong (CN)

(21) Appl. No.: 19/144,488

(22) PCT Filed: Oct. 20, 2023
(86) PCT No.: PCT/CN2023/125734

§ 371 Date: Jun. 29, 2025

(30) Foreign Application Priority Data
Dec. 30, 2022 (CN) 202211742552.0

(51) Int. Cl. H10K 85/10; B82Y 20/00; B82Y 40/00; C09K 11/02; C09K 11/88; H10K 71/12

(52) U.S. Cl. CPC H10K 85/114; C09K 11/025; C09K 11/883; H10K 71/12; B82Y 20/00; B82Y 40/00

(57) ABSTRACT

Provided is a composite material and a preparation method thereof, and a preparation method of a light-emitting device. The composite material includes a nanoparticle, a temperature-responsive polymer, and a solvent, the temperature-responsive polymer has a first gelation critical temperature, and when the temperature is lower than the first gelation critical temperature, the temperature-responsive polymer and the solvent are cross-linked to form a network structure, so that the movement and mutual aggregation of the nanoparticle is avoided, thereby improving the dispersity of the nanoparticles in the composite material.

The present disclosure claims priority to the Chinese patent application No. 202211742552.0, filed on Dec. 30, 2022, and entitled “COMPOSITE MATERIAL AND PREPARATION METHOD THEREOF, AND LIGHT-EMITTING DEVICE AND PREPARATION METHOD THEREOF”, the content of which is incorporated herein by reference in its entirety.

### TECHNICAL FIELD

The present disclosure relates to a technical field of display, in particular to a composite material and a preparation method thereof, and a preparation method of a light-emitting device.

### BACKGROUND

Nanomaterials refer to materials in which at least one dimension is in the nanometer range (1-100 nm) or are composed of them as basic units, which is approximately equivalent to the scale of 10-1000 atoms closely arranged together. When a macroscopic object is subdivided into nanomaterials with nanometer size, its optical, thermal, electrical, magnetic, mechanical and chemical properties all show significant differences.

Due to the unique performance of nanomaterials, they are widely used in various fields. For example, nanomaterials are widely used in light-emitting devices. Nanomaterials with light-emitting performance may be used to prepare light-emitting layers, and nanomaterials with electron transport performance may be used to prepare electron functional layers, etc.

However, due to the nanoscale size of nanomaterials, nanomaterials are prone to aggregation when used, thereby affecting their application. Therefore, how to improve the dispersibility of nanomaterials is one of the key problems in the application of nanomaterials.

### Technical Solution

The present disclosure provides a composite material and a preparation method thereof, and a preparation method of a light-emitting device.

In some embodiments of the present disclosure, a composite material is provided, including a nanoparticle, a temperature-responsive polymer and a solvent, wherein the temperature-responsive polymer has a first gelation critical temperature.

Optionally, in some embodiments of the present disclosure, the composite material consists of the nanoparticle, the temperature-responsive polymer and the solvent.

Optionally, in some embodiments of the present disclosure, when a temperature is below the first gelation critical temperature, the temperature-responsive polymer cross-links with the first solvent to form a network structure to cause the composite material to form a gel state; and/or when a temperature is above the first gelation critical temperature, the composite material is in a liquid state; and/or the nanoparticle is selected from a quantum dot.

Optionally, in some embodiments of the present disclosure, the temperature-responsive polymer is selected from one or more of poly(p-phenylenevinylene) and derivatives thereof; and/or the solvent includes a first solvent selected from limonene; and/or the temperature-responsive polymer has a peak wavelength of 450 nm to 490 nm and the quantum dot has a peak wavelength of 450 nm to 490 nm; or the temperature-responsive polymer has a peak wavelength of 500 nm to 560 nm and the quantum dot has a peak wavelength of 500 nm to 560 nm; or the temperature-responsive polymer has a peak wavelength of 580 nm to 700 nm and the quantum dot has a peak wavelength of 580 nm to 700 nm; and/or an average particle size of the quantum dot is 4-6 nm; and/or the quantum dot is selected from one or more of a single-structure quantum dot, a core-shell structure quantum dot, and a perovskite semiconductor material, the single-structure quantum dot is selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and the group I-III-VI compound is selected from one or more of CuInS₂, CuInSe₂, and AgInS₂, a core of the core-shell structure quantum dot is selected from any one of the single-structure quantum dots, and a shell material of the core-shell structure quantum dot is selected from one or more of CdS, CdTe, CdSeTe, CdZnSe, CdZnS, CdSeS, ZnSe, ZnSeS, and ZnS, the perovskite semiconductor material is selected from a doped or non-doped inorganic perovskite semiconductor or an organic-inorganic hybrid perovskite semiconductor, a general structure of the inorganic perovskite semiconductor is AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻; a general structure of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]₂⁺, wherein n is 2 or more, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻.

Optionally, in some embodiments of the present disclosure, a mass percentage of the limonene in the solvent is 70%-100%; and/or the solvent further includes a second solvent selected from one or more of chlorobenzene and chloroform.

Optionally, in some embodiments of the present disclosure, the temperature-responsive polymer is selected from one or more of PPV, P-PPV, CN-PPV, and DP-PPV; and/or a concentration of the temperature-responsive polymer in the composite material is 2 mg/mL to 3 mg/mL; and/or a concentration of the nanoparticle in the composite material is 20 mg/mL to 30 mg/mL; and/or the quantum dot has a peak wavelength of 500 nm to 560 nm; and/or the first gelation critical temperature ranges from 25° C. to 35° C.

Correspondingly, an embodiment of the present disclosure further provides a method of preparing a composite material, including: providing a nanoparticle, a temperature-responsive polymer, and a solvent, wherein the temperature-responsive polymer has a first gelation critical temperature; mixing the nanoparticle, the temperature-responsive polymer, and the solvent to obtain the composite material; when a temperature is below the first gelation critical temperature, the stimulus-responsive polymer cross-links with the first solvent to form a network structure to cause the composite material to form a gel state.

Optionally, in some embodiments of the present disclosure, the step of mixing the nanoparticle, the temperature-responsive polymer, and the solvent includes: mixing the nanoparticle, the temperature-responsive polymer, and the solvent at a first temperature to obtain the composite material, wherein the first temperature is greater than the first gelation critical temperature; and/or the nanoparticle is selected from a quantum dot.

Optionally, in some embodiments of the present disclosure, the temperature-responsive polymer is selected from one or more of poly(p-phenylene vinylene) and derivatives thereof; and/or the solvent includes a first solvent selected from limonene; and/or the first gelation critical temperature is greater than or equal to room temperature; and/or the temperature-responsive polymer has a peak wavelength of 450 nm to 490 nm and the quantum dot has a peak wavelength of 450 nm to 490 nm; or the temperature-responsive polymer has a peak wavelength of 500 nm to 560 nm and the quantum dot has a peak wavelength of 500 nm to 560 nm; or the temperature-responsive polymer has a peak wavelength of 580 nm to 700 nm and the quantum dot has a peak wavelength of 580 nm to 700 nm; and/or the quantum dot is selected from one or more of a single-structure quantum dot, a core-shell structure quantum dot, and a perovskite semiconductor material, the single-structure quantum dot is selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and the group I-III-VI compound is selected from one or more of CuInS₂, CuInSe₂, and AgInS₂, a core of the core-shell structure quantum dot is selected from any one of the single-structure quantum dots, and a shell material of the core-shell structure quantum dot is selected from one or more of CdS, CdTe, CdSeTe, CdZnSe, CdZnS, CdSeS, ZnSe, ZnSeS, and ZnS, the perovskite semiconductor material is selected from a doped or non-doped inorganic perovskite semiconductor or an organic-inorganic hybrid perovskite semiconductor, a general structure of the inorganic perovskite semiconductor is AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻; a general structure of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]₂⁺, wherein n is 2 or more, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻.

Optionally, in some embodiments of the present disclosure, the temperature-responsive polymer is selected from one or more of PPV, P-PPV, CN-PPV, and DP-PPV; and/or a concentration of the temperature-responsive polymer in the composite material is 2 mg/mL to 3 mg/mL; and/or a concentration of the nanoparticle in the composite material is 20 mg/mL to 30 mg/mL; and/or the solvent further includes a second solvent selected from one or more of chlorobenzene and chloroform; and/or a mass percentage of the limonene in the solvent is 70% to 100%; and/or the quantum dot has a peak wavelength of 500 nm to 560 nm.

Optionally, in some embodiments of the present disclosure, the temperature-responsive polymer is selected from P-PPV, and wherein the first gelation critical temperature ranges from 25° C. to 35° C.; and/or the first temperature ranges from 40° C. to 100° C.

Correspondingly, the present disclosure also provides a method of preparing a light-emitting device, including: providing a first electrode and a composite material, disposing the composite material on the first electrode to form a functional layer, and forming a second electrode on the functional layer; wherein the composite material is the composite material as described above or is obtained by the method of preparing the composite material.

Optionally, in some embodiments of the present disclosure, the composite material in a liquid state is disposed on the first electrode at a temperature of a second temperature, wherein the second temperature is greater than the first gelation critical temperature and the composite material is in a liquid state; then, the temperature is reduced to less than the first gelation critical temperature to cause the composite material disposed on the first electrode to transition from the liquid state to a gel state.

Optionally, in some embodiments of the present disclosure, after the step of disposing the composite material on the first electrode, the method further includes: a drying process to remove a solvent from the composite material to form the functional layer.

Optionally, in some embodiments of the present disclosure, the second temperature is 40° C. to 100° C.; and/or
the drying process has a pressure of 0.1 Pa to 1 Pa, and a temperature of 20° C. to 40° C.; and/or the functional layer is selected from one or more of an electron functional layer, a light-emitting layer, and a hole functional layer; and/or the first electrode and the second electrode are independently selected from a metal electrode, a carbon electrode, a doped or undoped metal oxide electrode, and a composite electrode; wherein a material of the metal electrode is selected from one or more of Al, Ag, Cu, Mo, Au, Ba, Ca, and Mg; a material of the carbon electrode is selected from one or more of graphite, carbon nanotubes, graphene, and carbon fibers; a material of the doped or undoped metal oxide electrode is selected from one or more of ITO, FTO, ATO, AZO, GZO, IZO, MZO, and AMO; and a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS.

Compared with the prior art, the composite material provided by the present disclosure includes the nanoparticle, the temperature-responsive polymer and the solvent, where the temperature-responsive polymer has the first gelation critical temperature. When the temperature falls below the first gelation critical temperature, the temperature-responsive polymer is crosslinked with the first solvent to form a network structure, so that the composite material transitions into a gel state, thereby relatively fixing the nanoparticle in the composite material in the gel state, avoiding movement and mutual aggregation of the nanoparticles, and thereby improving the dispersity of the nanoparticles in the composite material.

### BRIEF DESCRIPTION OF DRAWINGS

In order to more clearly illustrate the technical solutions in some embodiments of the present disclosure, the following will briefly introduce the drawings required in the embodiment description. Obviously, the drawings in the following description merely represent some of the embodiments of the present disclosure, and other drawings may be obtained by those skilled in the art without creative efforts.

FIG. 1 is a schematic diagram of state transition of a composite material provided by the present disclosure.

FIG. 2 is a flow chart of a method of preparing a composite material according to an embodiment of the present disclosure.

FIG. 3 is a flow chart of a method of preparing a composite material according to another embodiment of the present disclosure.

FIG. 4 is a flow chart of a method of preparing a composite material according to still another embodiment of the present disclosure.

FIG. 5 is a flow chart of a method of preparing a light-emitting device according to an embodiment of the present disclosure.

FIG. 6 is a schematic diagram of a process of a specific embodiment of step S22 in FIG. 5.

FIG. 7 is a schematic structural diagram of a light-emitting device according to an embodiment of the present disclosure.

### EMBODIMENTS OF THE PRESENT DISCLOSURE

The technical solutions in the embodiments of the present disclosure will be clearly and completely described below in combination with the drawings in the embodiments of the present disclosure. It is obvious that the described embodiments are only part of the embodiments of the present disclosure, rather than all the embodiments. Based on the embodiments in the present disclosure, all the other embodiments obtained by a person of ordinary skill in the art without creative work do not go beyond the protection scope of the present disclosure. In addition, it should be understood that the specific embodiments described herein are only used for illustration and explanation of the present disclosure, and are not used for limiting the present disclosure. In the present disclosure, the orientation words such as “upper” and “lower” are specifically the directions of the drawing surface in the drawings, unless otherwise specified. In addition, in the description of the present disclosure, the term “comprising” means “including but not limited to”. Various embodiments of the present disclosure can exist in the form of a range; it should be understood that the description in the form of a range is only for convenience and brevity, and should not be understood as a rigid limitation on the scope of the present disclosure; therefore, it should be considered that the range description has specifically disclosed all possible sub-ranges and single values in the range. For example, it should be considered that the range description from 1 to 6 has specifically disclosed sub-ranges, for example, from 1 to 3, from 1 to 4, from 1 to 5, from 2 to 4, from 2 to 6, from 3 to 6, etc., and single numbers in the range, for example, 1, 2, 3, 4, 5, and 6, which are applicable regardless of the range. In addition, whenever a numerical range is indicated herein, it is meant to include any cited number (fractional or integral) within the indicated range.

In the present disclosure, “and/or” describing the association relationship of the associated objects indicates that there may be three relationships, for example, A and/or B can indicate that A exists alone, A and B exist simultaneously, and B exists alone. Wherein A and B may be singular or plural.

In the present disclosure, “at least one” means one or more, and “a plurality of” means two or more. “At least one”, “at least one of”, or the like, means any combination of the items, including any combination of a single item or multiple items. For example, “at least one of a, b, or c”, or “at least one of a, b, and c”, can indicate a, b, c, a-b (i.e., a and b), a-c, b-c, or a-b-c, wherein a, b, and c may be a single item or multiple items.

The present disclosure provides a composite material including a nanoparticle, a stimuli-responsive polymer, and a solvent, where the composite material has a characteristic of reversible gelation transition under external stimulation.

In the embodiment, the nanoparticle refers to a material with at least one dimension in nanoscale (1-100 nm) in three-dimensional space, also known as a nanomaterial. It may be understood that the nanoparticle include a nanoparticle, a nanotube, a nanosheet, etc.

In the embodiment, the composite material has the characteristic of reversible gelation transition under external stimulation by adding the stimulus-responsive polymer and the solvent into the composite material. That is, the composite material can realize the reversible transition between a gel state and a liquid state. When the composite material is in the liquid state, the stimulus-responsive polymer is dissolved in the solvent, and each component in the composite material can move freely, mix and disperse sufficiently. After the composite material is gelled, the stimulus-responsive polymer and the solvent self-assemble and cross-link to form a spatial or three-dimensional network structure, and the nanoparticle is fixed in the network structure, so that the nanoparticle is relatively fixed in the composite material in the gel state, nanoparticles are prevented from moving and aggregating with each other, and the dispersion of the nanoparticles in the composite material is improved. The composite material in the gel state may also support long-term storage of the nanoparticles, so that the nanoparticles may still maintain good dispersion uniformity even during long-term storage; and the composite material in the gel state may improve the transportation convenience. When the composite material needs to be used, on the one hand, the composite material in the gel state may be directly used, which may reduce the application difficulty of the composite material in an application scenario where the flow of the composite material needs to be limited, and on the other hand, the composite material in the gel state may be converted into the liquid state, so that the composite material has a flow state, thereby being applicable to various different application scenarios, such as coating application scenarios.

In an embodiment, the composite material may be composed of the nanoparticle, the stimulus-responsive polymer and the solvent. That is, the composite material only includes the nanoparticle, the stimulus-responsive polymer and the solvent, and does not include other components. In another embodiment, the composite material may further include other materials, such as materials with adhesiveness, etc.

In an embodiment, the external stimulation includes a first external stimulation. When the composite material is in the liquid state, the stimulus-responsive polymer and the solvent cross-link to form a network structure under the first external stimulation, so that the composite material is gelled. In the embodiment, the nanoparticles may be fixed in the network structure by self-assembling and cross-linking the stimulus-responsive polymer and the solvent to form a three-dimensional network structure, the aggregation of the nanoparticles caused by free movement of the nanoparticle is avoided, the dispersion uniformity of the nanoparticles in the composite material is improved, the composite material may still have good dispersion during long-term storage, and the transportation convenience is improved.

In an embodiment, the external stimulus includes a second external stimulation. When the composite material is in the gel state, the composite material is transformed from the gel state to the liquid state under the second external stimulation. In this embodiment, the composite material is reversibly transformed into the liquid state, thereby improving the convenience of application of the composite material, so that the composite material may be applied to different application scenarios. For example, the composite material may be processed into different target shapes, and may be used to prepare a film layer with a preset pattern or a film layer with a preset thickness.

In the above embodiment, the composite material may be reversibly transformed between the liquid state and the gel state through the first external stimulation and the second external stimulation, thereby improving the dispersibility and wide applicability of the composite material. In addition, by changing the state of the composite material, such as transforming the liquid state into the gel state, the composite material may have a preset shape. For example, the preset shape refers to a film layer with a preset thickness, a module (such as a spheroid) with a preset pattern, or the like. That is, the state and the shape of the composite material may be flexibly changed according to corresponding requirements. In addition, the composite material in the gel state may be prepared in advance, the composite material in the gel state has a preset shape, may be stored and transported for a long time, and may be directly used when needed.

In an embodiment, the stimulus-responsive polymer is selected from a temperature-responsive polymer. The temperature-responsive polymer refers to a polymer that, under the stimulus of temperature change, the molecular structure of the polymer reversibly or irreversibly changes, or the solubility of the polymer changes, thereby causing the shape or phase state of a system containing the temperature-responsive polymer to change. The transition of the phase states includes the transition between the liquid state and the gel state.

In an embodiment, the composite material includes a nanoparticle, a temperature-responsive polymer, and a solvent, wherein the temperature-responsive polymer has a first gelation critical temperature.

The temperature-responsive polymer has a first gelation critical temperature. The first external stimulation refers to a temperature lower than the first gelation critical temperature, and the second external stimulation refers to a temperature higher than the first gelation critical temperature.

In combination with FIG. 1, the first gelation critical temperature refers to a critical temperature at which the temperature-responsive polymer is transformed. When the temperature falls below the first gelation critical temperature (i.e., under the first external stimulation), the stimulus-responsive polymer is crosslinked with the solvent to form a network structure to gel the composite material. When a temperature rises over the first gelation critical temperature (i.e., under the second external stimulation), the composite material is transformed from the gel state to the liquid state.

In the embodiment, the reversible change of the state of the composite material may be achieved by changing the temperature, which is simple and convenient, and improves the convenience of using the composite material.

In a specific embodiment, the first gelation critical temperature is greater than or equal to room temperature. When the temperature is less than the first gelation critical temperature (i.e. under the first external stimulation), such as at room temperature, the composite material may be changed into and maintained in the gel state, thereby improving the convenience of using the composite material and improving the convenience of changing the state of the composite material. It may be understood that the room temperature generally refers to about 25° C., specifically 25° C.±5° C., i.e. a temperature range of 20-30° C.

In an embodiment, the temperature-responsive polymer is selected from one or more of poly(p-phenylene vinylene) and derivatives thereof. Specifically, the temperature-responsive polymer may be selected from one or more of PPV, P-PPV, CN-PPV, and DP-PPV, and the structural formulas of PPV, P-PPV, CN-PPV, and DP-PPV are as follows, respectively:

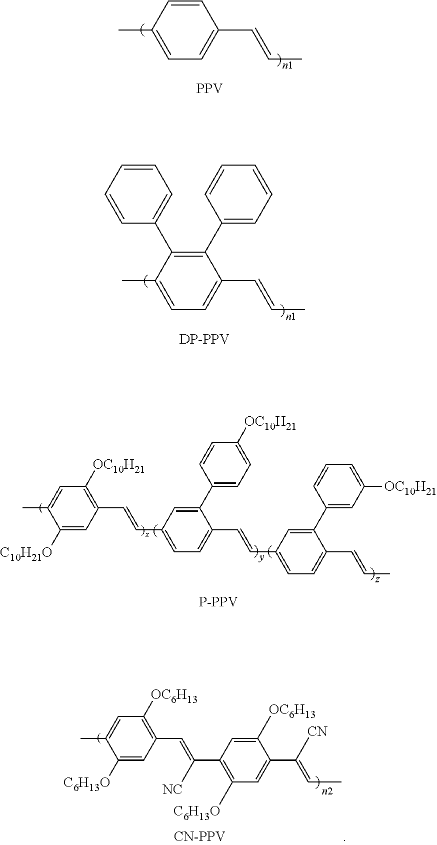

Specifically, the temperature-responsive polymer may be obtained commercially or prepared by a known preparation method.

In a specific embodiment, the temperature-responsive polymer is P-PPV, and the reaction formula for synthesizing P-PPV is as follows:

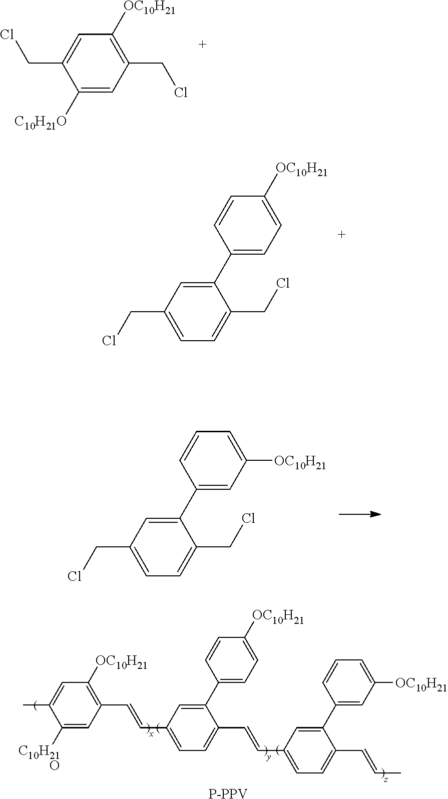

Specifically, the three raw materials and potassium tert-butoxide are dissolved in dioxane, and a reflux heating reaction is performed to obtain P-PPV.

It may be understood that the poly(p-phenylene vinylene) and derivatives thereof include homopolymers and copolymers formed by monomers, where the monomers may be selected from one or more of p-phenylene vinylene and derivatives thereof. The homopolymer is a polymer formed by only one kind of monomer, and the copolymer is a polymer formed by two or more kinds of monomers. The copolymer further includes an alternating copolymer, a random copolymer, a block copolymer, etc. The alternating copolymer is a copolymer in which monomers are alternated, the random copolymer is a copolymer in which monomers are randomly combined, and the block copolymer is a copolymer in which monomers are attached in blocks.

In an embodiment, the solvent includes a first solvent selected from limonene. In an embodiment, under the first stimulus, the benzene ring or the double bond of P-PPV may form 7L-7L conjugation with the double bond of limonene, form non-covalent bond (such as van der Waals force, etc.) cross-linking, thereby forming a cross-linked network structure, and causing the composite material to gelate.

Specifically, a mass percentage of the limonene in the solvent is 70% to 100%, and may be specifically 70% to 80%, 80% to 90%, 90% to 100%, 70% to 90%, 80% to 100%, etc. Based on the limonene with the mass percentage, the solvent may be cross-linked with the stimulus-responsive polymer to form a network structure, so that the composite material is gelled.

It can be understood that when the mass percentage of the limonene in the solvent is 100%, it means that the solvent is a single solvent, that is, the solvent is all limonene. When the mass percentage of the limonene in the solvent is less than 100%, the solvent may further include other solvents, that is, the solvent is a mixed solvent formed by two or more solvents.

In an embodiment, the solvent further includes a second solvent in addition to the first solvent. The second solvent is selected from at least one of chlorobenzene and chloroform. The second solvent may promote the dissolution of the temperature-responsive polymer such as poly(p-phenylenevinylene) and derivatives thereof in the solvent.

In an embodiment, a concentration of the temperature-responsive polymer in the composite material is greater than 2 mg/mL. Based on the temperature-responsive polymer with the concentration, the composite material may be formed into the gel state.

In a specific embodiment, the concentration of the temperature-responsive polymer in the composite material is 2 mg/mL to 3 mg/mL, and may be specifically 2 mg/mL to 2.3 mg/mL, 2 mg/mL to 2.8 mg/mL, 2.3 mg/mL to 2.8 mg/mL, 2.3 mg/mL to 2.5 mg/mL, 2.5 mg/mL to 3 mg/mL, 2.8 mg/mL to 3 mg/mL, etc. The temperature-responsive polymer with the concentration may support the temperature-responsive polymer to be cross-linked with the solvent to form a network structure, so that the composite material may be formed into the gel state, and may also provide a network structure with a suitable density, so that the nanoparticles may be uniformly dispersed in the network structure.

A concentration of the nanoparticle in the composite material is 20 mg/mL to 30 mg/mL, and may be specifically 20 mg/mL to 28 mg/mL, 22 mg/mL to 28 mg/mL, 22 mg/mL to 25 mg/mL, 28 mg/mL to 30 mg/mL, etc. The nanoparticle with the concentration may be uniformly dispersed in the composite material.

In an embodiment, the nanoparticle may be selected from a quantum dot, and the composite material may have a luminescent property. Further, a concentration of the quantum dot in the composite material is 20 mg/mL to 30 mg/mL, so that the composite material has a better luminescent property.

In an embodiment, an average particle size of the quantum dots is 4 nm to 6 nm, and may be specifically 4 nm to 5 nm, 5 nm to 6 nm, etc.

The quantum dots may be selected from at least one of a single-structure quantum dot, a core-shell structure quantum dot, and a perovskite semiconductor material. The single-structure quantum dot is selected from at least one of a group II-VI compound, a group IV-VI compound, a group III-V compound, and a group I-III-VI compound. The group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe.

The group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe. The group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb. The group I-III-VI compound is selected from at least one of CuInS₂, CuInSe₂, and AgInS₂. A core of the core-shell structure quantum dot is selected from any one of the single-structure quantum dots. A shell material of the core-shell structure quantum dot is selected from at least one of CdS, CdTe, CdSeTe, CdZnSe, CdZnS, CdSeS, ZnSe, ZnSeS, and ZnS. The perovskite semiconductor material is selected from a doped or non-doped inorganic perovskite semiconductor or an organic-inorganic hybrid perovskite semiconductor. A general structure of the inorganic perovskite semiconductor is AMX₃. A is a Cs⁺ ion, M is a divalent metal cation selected from at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from at least one of Cl⁻, Br⁻, and I⁻. A general structure of the organic-inorganic hybrid perovskite semiconductor is BMX₃. B is an organic amine cation selected from CH₃(CH₂)ₙ₋₂NH₃⁺ or [NH₃(CH₂)ₙNH₃]₂⁺, where n is 2 or more. M is a divalent metal cation selected from at least one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺. X is a halide anion selected from at least one of Cl⁻, Br⁻, and I⁻.

Further, in an embodiment, the fluorescence color of the stimulus-responsive polymer is the same as the light-emitting color of the quantum dot. In this embodiment, the stimulus-responsive polymer and the quantum dot have the same color, thereby improving the consistency of the light-emitting color and the light-emitting intensity of the composite material. Specifically, the fluorescence color of the stimulus-responsive polymer is red, and the light-emitting color of the quantum dot is also red; the fluorescence color of the stimulus-responsive polymer is green, and the light-emitting color of the quantum dot is also green; the fluorescence color of the stimulus-responsive polymer is blue, and the light-emitting color of the quantum dot is also blue.

Further, a fluorescence wavelength of the temperature-responsive polymer matches a light-emitting wavelength of the quantum dot, for example, the fluorescence wavelength of the temperature-responsive polymer is in the red light wavelength range, and the light-emitting wavelength of the quantum dot is also in the red light wavelength range. In a specific embodiment, the fluorescence wavelength of the temperature-responsive polymer is 450-490 nm, and the light-emitting wavelength of the quantum dot is 450-490 nm; or the fluorescence wavelength of the temperature-responsive polymer is 500-560 nm, and the light-emitting wavelength of the quantum dot is 500-560 nm; or the fluorescence wavelength of the temperature-responsive polymer is 580-700 nm, and the light-emitting wavelength of the quantum dot is 580-700 nm. It can be understood that, in the present disclosure, the fluorescence wavelength and the light-emitting wavelength both refer to the peak wavelength. The peak wavelength specifically refers to the wavelength corresponding to the maximum amplitude point on the entire spectrum.

In a specific embodiment, the temperature-responsive polymer is P-PPV, which has a green fluorescence color, and the quantum dot is a green quantum dot, that is, the light-emitting color is green (i.e., the light-emitting wavelength is 500-560 nm), so that the composite material may emit green light, thereby improving the light-emitting intensity and the purity of the light-emitting color of the composite material.

In a specific embodiment, the composite material includes a green quantum dot, P-PPV, and a solvent. The solvent is prepared from chlorobenzene and limonene according to the mass ratio of 3:7. The first gelation critical temperature of the composite material is 35° C. The first external stimulation is a temperature lower than 35° C., for example, room temperature. The second external stimulation is a temperature higher than 35° C., for example, 40-100° C., specifically 60° C. The first gelation critical temperature is low, so that the composite material may be converted into the gel state at room temperature, and may be converted into the liquid state under heating at a lower temperature, so as to avoid damaging the quantum dot at the heating temperature.

It can be understood that, in this embodiment, the temperature-responsive polymer may have only temperature responsiveness, or may have one or more of photoelectric responsiveness, pH responsiveness, etc. in addition to temperature responsiveness. In other embodiments, the stimulus-responsive polymer may also be selected from one or more of photoelectric-responsive polymers, pH-responsive polymers, etc.

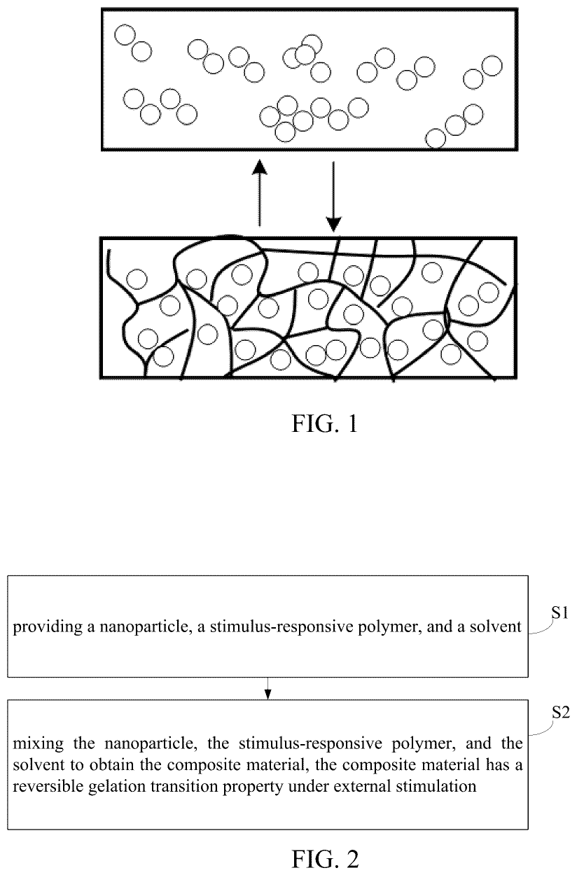

The present disclosure also provides a method of preparing a composite material. Referring to FIG. 2, which is a flow chart of a method of preparing the composite material according to an embodiment of the present disclosure. The method includes the following steps:
S1: providing a nanoparticle, a stimulus-responsive polymer, and a solvent;
S2: mixing the nanoparticle, the stimulus-responsive polymer, and the solvent to obtain the composite material. The composite material has a reversible gelation transition property under external stimulation.

In this embodiment, the composite material is obtained by mixing the nanoparticle, the stimulus-responsive polymer, and the solvent, so that the composite material has a characteristic of reversible gelation transition under external stimulation, that is, the composite material may realize reversible transition between a gel state and a liquid state. When the composite material is in the liquid state, the components in the composite material may be fully mixed and dispersed, and then the composite material is gelled, so that nanoparticles are relatively fixed in the composite material in the gel state, avoiding movement and mutual aggregation of the nanoparticles, thereby improving the dispersity of the nanoparticles in the composite material. The composite material in the gel state may also support long-term storage of the nanoparticles and improve transportation convenience. When the composite material needs to be used, on the one hand, the composite material may be directly used in the gel state, avoiding flow of the composite material to reduce application difficulty, and on the other hand, the composite material in the gel state may be converted into the liquid state, so that the composite material has a flow state, to be suitable for various application scenarios.

The external stimulation may include a first external stimulation. When the composite material is in the liquid state, the first external stimulation is applied to the composite material, so that the stimulus-responsive polymer is crosslinked with the first solvent to form a network structure, and the composite material is gelled. And/or the external stimulation may also include a second external stimulation. When the composite material is in the gel state, the second external stimulation is applied to the composite material, so that the composite material is converted from the gel state to the liquid state.

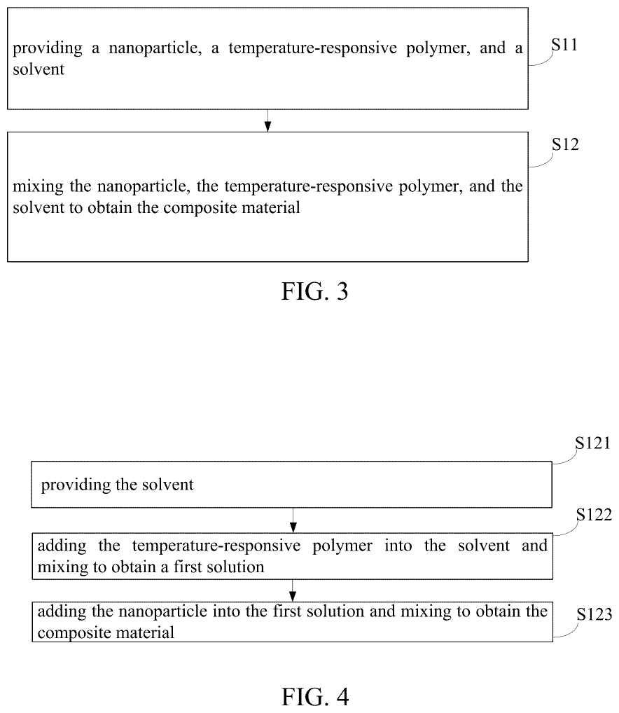

Referring to FIG. 3, which is a flow chart of a method of preparing the composite material according to another embodiment of the present disclosure. The method includes the following steps:
step S11, providing a nanoparticle, a temperature-responsive polymer, and a solvent, where the temperature-responsive polymer has a first gelation critical temperature; and,
step S12, mixing the nanoparticle, the temperature-responsive polymer, and the solvent to obtain the composite material.

When the temperature falls below the first gelation critical temperature, the stimulus-responsive polymer is crosslinked with the first solvent to form a network structure, and the composite material is in the gel state.

In the step S11,
the nanoparticle, the temperature-responsive polymer and the solvent may be referred to the corresponding content in the composite material part described above, and will not be repeated here.

In the step S12:
in an embodiment, the step of mixing the nanoparticle, the temperature-responsive polymer and the solvent may be specifically: mixing the nanoparticle, the temperature-responsive polymer and the solvent at a first temperature to obtain the composite material; wherein the first temperature is greater than the first gelation critical temperature. In this embodiment, the first temperature greater than the first gelation critical temperature may accelerate the mutual mixing and dissolving of the nanoparticle, the temperature-responsive polymer and the solvent.

Referring to FIG. 4, FIG. 4 is a flow chart of a method of preparing the composite material according to another embodiment of the present disclosure. In an embodiment, the step of mixing the nanoparticles, the stimulus-responsive polymer and the solvent includes:
Step S121: providing the solvent;
Step S122: adding the temperature-responsive polymer into the solvent and mixing to obtain a first solution;
Step S123: adding the nanoparticle into the first solution and mixing to obtain the composite material.

In this embodiment, the dispersion and uniformity of each component in the composite material are improved by adding in multiple steps and mixing multiple times.

In a specific embodiment, in the step S121, the solvent is prepared from chlorobenzene and limonene at a mass ratio of 3:7. In the step S122, P-PPV is added into the solvent, and heated and stirred at 40-100° C. for 4 h. In the step S123, a green quantum dot is added into the first solution, and heated and stirred at 40-100° C. for 30 min.

In this embodiment, the first gelation critical temperature of the composite material obtained is 35° C. The first external stimulation is a temperature less than 35° C., such as room temperature. The second external stimulation is a temperature higher than 35° C., such as 40-100° C., specifically 40-50° C., 50-60° C., 60-70° C., 70-80° C., 80-90° C., 90-100° C., etc. The low first gelation critical temperature may allow the composite material to be converted into a gel state at room temperature, and be converted into a liquid state under heating at a low temperature, thereby avoiding damage to quantum dots caused by a high heating temperature.

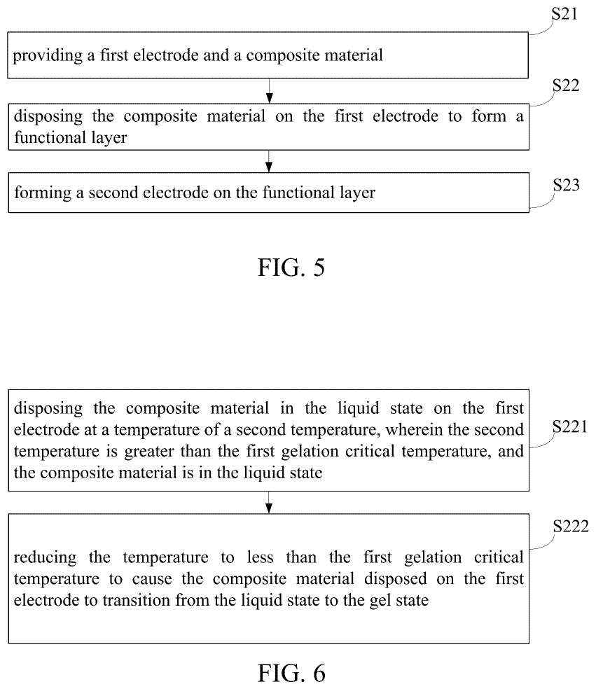

Referring to FIG. 5, FIG. 5 is a flow chart of a method of preparing a light-emitting device according to an embodiment of the present disclosure. The method includes the following steps:
Step S21: providing a first electrode and a composite material;
Step S22: disposing the composite material on the first electrode to form a functional layer;
Step S23: forming a second electrode on the functional layer.

The composite material is the composite material provided by the present disclosure.

In the embodiment, the nanoparticle is well dispersed in the composite material. The composite material forms the functional layer, thereby improving the dispersion uniformity of the functional layer, and improving the stability and reliability of the light-emitting device.

In the step S21,
in an embodiment, the composite material may be in the gel state or the liquid state.

In a specific embodiment, the composite material in the gel state may have a film shape with a preset thickness. In the step S22, the composite material with the film shape with the preset thickness may be directly disposed on the first electrode, which is simple and fast.

In another specific embodiment, the composite material may be in the gel state. In the step S22, an external stimulus may be applied to the composite material in the gel state to convert the composite material in the gel state into a composite material in a liquid state, and then the composite material in the liquid state is disposed on the first electrode. For example, the solution method may be used in the disposing.

In the step S22,
in an embodiment, after the step of disposing the composite material on the first electrode, the method further includes: a drying process to remove a solvent from the composite material to form the functional layer. It can be understood that, after the solvent is removed, the functional layer obtained will not have the characteristic of reversible gelation under the external stimulus possessed by the composite material, that is, the functional layer will not become liquid, and the functional layer will have a stable structure and state.

In a specific embodiment, a pressure of the drying treatment is 0.1-1 Pa, a time of the drying treatment is 30-60 min, and a temperature of the drying treatment is 20-40° C.

Referring to FIG. 6, FIG. 6 is a schematic diagram of a specific embodiment of the step S22 in FIG. 5. The step S22 specifically includes the following steps:
Step S221: disposing the composite material in the liquid state on the first electrode at a temperature of a second temperature, wherein the second temperature is greater than the first gelation critical temperature, and the composite material is in the liquid state; and
Step S222: reducing the temperature to less than the first gelation critical temperature to cause the composite material disposed on the first electrode to transition from the liquid state to the gel state.

The second temperature is 40-100° C., and may be specifically 40-50° C., 50-60° C., 60-70° C., 70-80° C., 80-90° C., 90-100° C., etc.

In this embodiment, the composite material is first converted into the liquid state, so that the composite material may be more easily and flexibly disposed on the first electrode, and then the composite material in the liquid state disposed on the first electrode is converted into the gel state, so that the composite material disposed on the first electrode maintains good dispersibility and uniformity. When a subsequent drying process is performed to form the functional layer, the uniformity of the distribution of each material, including nanoparticles, in the functional layer may be improved.

In an embodiment, the functional layer may be one or more of various layers in the light-emitting device. Specifically, the functional layer may be selected from one or more of an electron functional layer, a light-emitting layer, and a hole functional layer. It can be understood that, in order to adapt to the functions of different functional layers, the nanoparticle, the stimulus-responsive polymer, and the solvent in the composite material may all be changed and adjusted accordingly.

In a specific embodiment, the functional layer includes the light-emitting layer, and the nanoparticle in the composite material may be a quantum dot. In this embodiment, the light-emitting layer formed by the composite material may improve the light-emitting uniformity of the light-emitting layer, and improve the reliability and stability of the light-emitting device.

A thickness of the light-emitting layer formed by the composite material may be 15-25 nm, and may be specifically 15-20 nm, 20-25 nm, etc.

It may be understood that, in this embodiment, the first electrode and the second electrode are a pair of electrodes. When the first electrode is an anode, the second electrode is a cathode; when the first electrode is a cathode, the second electrode is an anode.

Further, the functional layer may further include the hole functional layer disposed between the anode and the light-emitting layer. Correspondingly, the nanoparticle in the composite material may be selected from nanoparticles having hole injection performance and/or hole transport performance, and may be specifically selected from one or more of doped or non-doped NiO, MoO₃, WO₃, V₂O₅, P-type gallium nitride, CrO₃, CuO, MoS₂, MoSe₂, WS₃, WSe₃, CuS, and CuSCN.

Further, the functional layer may further include the electron functional layer disposed between the cathode and the light-emitting layer. Correspondingly, the nanoparticle in the composite material may be selected from nanoparticles having electron injection performance and/or electron transport performance, and may be specifically selected from at least one of doped inorganic nanocrystals or non-doped inorganic nanocrystals. The non-doped inorganic nanocrystals are selected from one or more of ZnO, TiO₂, SnO₂, Al₂O₃, GaO, Ga₂O₃, ZrO₂, Fe₂O₃, CrO₃, WO₃, CdO, CuO, MoO₂, ZnS, ZnSe, CdS, InP, GaP, LiF, LiF/Yb, MgP, MgF₂, Ga₂O₃, Cs₂CO₃, Rb₂CO₃, and RbBr. The doped inorganic nanocrystals include the non-doped inorganic nanocrystals and a doping element, and the doping element is selected from one or more of Mg, Ca, Li, Ga, Al, Co, and Mn.

In an embodiment, the first electrode and the second electrode are independently selected from a metal electrode, a carbon electrode, a doped or non-doped metal oxide electrode, and a composite electrode. The metal electrode is made of a material selected from at least one of Al, Ag, Cu, Mo, Au, Ba, Ca, and Mg; the carbon electrode is made of a material selected from at least one of graphite, carbon nanotube, graphene, and carbon fiber; the doped or non-doped metal oxide electrode is made of a material selected from at least one of ITO, FTO, ATO, AZO, GZO, IZO, MZO, and AMO; and the composite electrode is made of a material selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS. Herein, “/” represents a stacked structure, for example, the composite electrode AZO/Ag/AZO represents an electrode with a composite structure of three layers of AZO layer, Ag layer, and AZO layer stacked together.

In the method of preparing the light-emitting device, the first electrode, the second electrode, and other layers may be prepared by using conventional techniques in the field, such as chemical methods or physical methods. The chemical methods include chemical vapor deposition, successive ionic layer adsorption and reaction, anodic oxidation, electrolytic deposition, and co-precipitation. The physical methods include physical coating methods and solution methods. The physical coating methods include thermal evaporation coating, electron beam evaporation coating, magnetron sputtering, multi-arc ion coating, physical vapor deposition, atomic layer deposition, pulsed laser deposition, and the like. The solution methods include spin coating, printing, inkjet printing, blade coating, printing, dip coating, immersion, spraying, roller coating, casting, slot die coating, stripe coating, and the like.

The present disclosure also provides a light-emitting device prepared by the method.

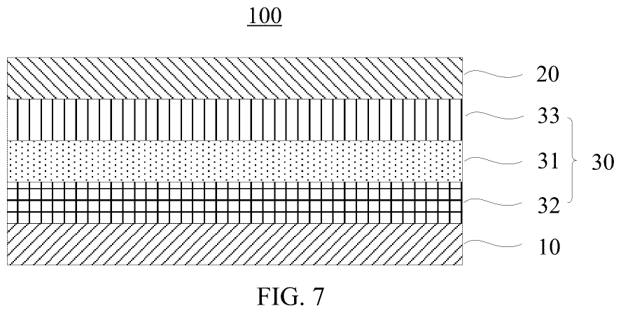

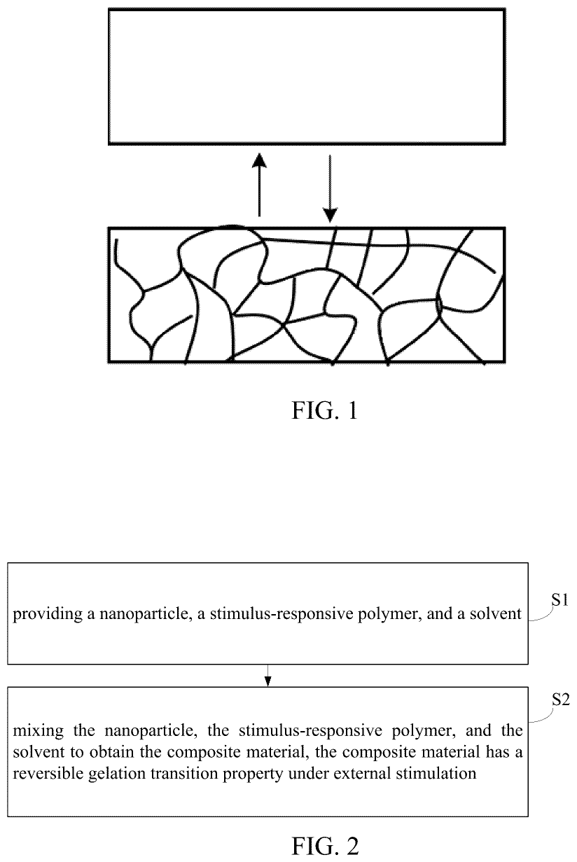

Referring to FIG. 7, FIG. 7 is a schematic structural diagram of a light-emitting device according to an embodiment of the present disclosure. The light-emitting device includes a first electrode 10, a second electrode 20, and a functional layer 30. The first electrode 10 and the second electrode 20 are oppositely arranged, and the functional layer 30 is arranged between the first electrode 10 and the second electrode 20. The functional layer 30 includes one or more of a light-emitting layer 31, a hole functional layer 32, and an electron functional layer 33.

The first electrode 10 and the second electrode 20 are a pair of electrodes. When the first electrode 10 is an anode, the second electrode 20 is a cathode; when the first electrode 10 is a cathode, the second electrode 20 is an anode.

In an embodiment, the hole functional layer 32 is arranged between the anode and the light-emitting layer 31. The hole functional layer 32 can include a hole injection layer and/or a hole transport layer. When the hole functional layer 32 includes both the hole injection layer and the hole transport layer, the hole injection layer is arranged on the side close to the anode, and the hole transport layer is arranged on the side close to the light-emitting layer 31.

A material of the hole transport layer is selected from one or more of poly(9,9-dioctylfluorene-CO—N-(4-butylphenyl)diphenylamine) (TFB), polyvinylcarbazole (PVK), poly(N,N′-bis(4-butylphenyl)-N,N′-bis(phenyl)benzidine) (poly-TPD), poly(9,9-dioctylfluorene-co-bis-N,N-phenyl-1,4-phenylenediamine) (PFB), 4,4′,4″-tris(carbazol-9-yl)triphenylamine (TCATA), 4,4′-bis(9-carbazolyl)biphenyl (CBP), N,N′-diphenyl-N,N′-di(3-methylphenyl)-1,1′-biphenyl-4,4′-diamine (TPD), N,N′-Bis(1-naphthalenyl)-N,N′-bisphenyl-(1,1′-biphenyl)-4,4′-diamine (NPB), poly(3,4-ethylenedioxythiophene)-poly(styrenesulfonic acid) (PEDOT:PSS), Spiro-NPB, Spiro-TPD, doped or undoped NiO, MoO₃, WO₃, V₂O₅, P-type gallium nitride, CrO₃, CuO, MoS₂, MoSe₂, WS₃, WSe₃, CuS, and CuSCN.

A material of the hole injection layer is a material having hole injection capability, and is selected from one or more of poly(3,4-ethylenedioxythiophene)-polystyrenesulfonic acid (PEDOT:PSS), 2,3,5,6-tetrafluoro-7,7′,8,8′-tetracyanoquinodimethane (F4-TCNQ), 2,3,6,7,10,11-hexacyano-1,4,5,8,9,12-hexaazatriphenylene (HATCN), copper phthalocyanine (CuPc), a transition metal oxide, and a transition metal chalcogenide; wherein the transition metal oxide includes one or more of NiO, MoO₂, WO₃, and CuO; and the transition metal chalcogenide includes one or more of MoS₂, MoSe₂, WS₃, WSe₃, and CuS.

In an embodiment, the electron functional layer 33 is disposed between the cathode and the light-emitting layer 31. The electron functional layer 33 may include an electron injection layer and/or an electron transport layer. When the electron functional layer 33 includes both the electron injection layer and the electron transport layer, the electron injection layer is disposed closer to the cathode, and the electron transport layer is disposed closer to the light-emitting layer 31.

A material of the electron transport layer may be a material known in the art for an electron transport layer, for example, may be selected from one or more of doped inorganic nanocrystals or non-doped inorganic nanocrystals, organic materials. The non-doped inorganic nanocrystals are selected from one or more of ZnO, TiO₂, SnO₂, Al₂O₃, GaO, Ga₂O₃, ZrO₂, Fe₂O₃, CrO₃, WO₃, CdO, CuO, MoO₂, ZnS, ZnSe, CdS, InP, GaP; the doped inorganic nanocrystals include the non-doped inorganic nanocrystals and a doping element, the doping element is selected from one or more of Mg, Ca, Li, Ga, Al, Co, Mn; the organic material is selected from one or both of polymethyl methacrylate and polyvinyl butyral.

In an embodiment, a material of the electron injection layer is a material known in the art for an electron injection layer, for example, may be selected from, but not limited to, at least one of LiF, LiF/Yb, MgP, MgF₂, Al₂O₃, Ga₂O₃, ZnO, Cs₂CO₃, Rb₂CO₃, and RbBr.

In an embodiment, a nanoparticle included in the hole functional layer 32 may be a quantum dot. The hole functional layer 32 is disposed between the anode and the light-emitting layer 31, and is disposed close to the side of the light-emitting layer 31, as an interface layer or a transition layer between the light-emitting layer 31 and the anode.

Similarly, in an embodiment, a nanoparticle included in the electron functional layer 33 may be a quantum dot. The electron functional layer 33 is disposed between the cathode and the light-emitting layer 31, and is disposed close to the side of the light-emitting layer 31, as an interface layer or a transition layer between the light-emitting layer 31 and the cathode.

It may be understood that the light-emitting device 100 may further include some functional layers commonly used in light-emitting devices, such as an electron blocking layer, an electron injection layer, a hole blocking layer, and/or an interface modification layer, etc., in addition to the above functional layers.

It may be understood that the materials and thicknesses of the layers of the light-emitting device 100 may be set and adjusted according to the light-emitting requirements of the light-emitting device 100.

The light-emitting device 100 further includes a substrate (not shown). The substrate may be a rigid substrate or a flexible substrate. The rigid substrate may be a ceramic material or various glass materials, etc. The flexible substrate may be formed of a substrate made of polyimide film (PI) and derivatives thereof, polyethylene naphthalate (PEN), phosphoenolpyruvic acid (PEP), or diphenylene ether resin, etc.

It is to be understood that the light-emitting device 100 may be an upright light-emitting device or an inverted light-emitting device. When the light-emitting device 100 is a upright light-emitting device, the substrate is bonded to the side of the anode away from the light-emitting layer 31. When the light-emitting device 100 is an inverted light-emitting device, the substrate is bonded to the side of the cathode away from the light-emitting layer 31.

It is to be understood that the light-emitting device 100 may further include some functional layers commonly used in light-emitting devices, such as an electron blocking layer, an electron injection layer, a hole blocking layer, an interface modification layer, etc.

It is to be understood that the materials and thicknesses of the layers of the light-emitting device 100 may be set and adjusted according to the light-emitting requirements of the light-emitting device 100.

The present disclosure also relates to a display device including the light-emitting device provided by the present disclosure. The display device may be any electronic product having a display function. The electronic product includes, but is not limited to, a smartphone, a tablet computer, a notebook computer, a digital camera, a digital video camera, a smart wearable device, a smart weighing electronic scale, a vehicle-mounted display, a television, or an e-book reader. The smart wearable device may be, for example, a smart bracelet, a smart watch, a Virtual Reality (VR) helmet, or the like.

The present disclosure is described below in detail through specific examples. The following examples are only part of the examples of the present disclosure, and are not limiting of the present disclosure.

### EXAMPLE 1

Example 1 provides a composite material and a preparation method thereof. The method specifically includes the following steps. Chlorobenzene and limonene were prepared according to a mass ratio of 3:7 to form a solvent. P-PPV was added into the solvent, heated and stirred at 60° C. for 4 h, then green quantum dots CdZnSe/ZnSe/ZnS were added, heated and stirred at 60° C. for 30 min to obtain a composite material 1. When cooled to room temperature, the composite material 1 changed from a liquid state to a gel state. A concentration of the green quantum dots was 25 mg/ml, and a concentration of the P-PPV was 2 mg/ml.

### EXAMPLE 2

The present example is similar to Example 1 except that the concentration of P-PPV in the composite material 2 was 3 mg/ml.

### EXAMPLE 3

The present example is similar to Example 1 except that the concentration of P-PPV in the composite material 3 was 4 mg/ml.

### EXAMPLE 4

The present example is similar to Example 1 except that the concentration of the green quantum dots in the composite material 4 was 30 mg/ml.

### EXAMPLE 5

This example is similar to Example 1, except that the concentration of the green quantum dots in the composite material 5 was 20 mg/ml.

### EXAMPLE 6

This example is similar to Example 1, except that DP-PPV was used instead of P-PPV in the composite material 8.

### EXAMPLE 7

This example is similar to Example 1, except that green quantum dots CdSe/ZnSeS/ZnS were used instead of green quantum dots CdZnSe/ZnSe/ZnS in the composite material 9.

### COMPARATIVE EXAMPLE 1

This comparative example is similar to Example 1, except that the concentration of P-PPV in the composite material 10 is 1 mg/ml.

### COMPARATIVE EXAMPLE 2

This comparative example is similar to Example 1, except that the mass ratio of chlorobenzene to limonene in the composite material 11 was 1:1.

### COMPARATIVE EXAMPLE 3

This comparative example is similar to Example 1, except that the concentration of the green quantum dots in the composite material 6 was 40 mg/ml.

### COMPARATIVE EXAMPLE 4

This comparative example is similar to Example 1, except that the concentration of the green quantum dots in the composite material 7 was 10 mg/ml.

### DEVICE EXAMPLE 1

Device Example 1 provides a quantum dot light-emitting diode and a preparation method thereof. The method specifically includes the following steps.
Step 1: a substrate plated with ITO (the thickness of the ITO layer is 30 nm) was ultrasonically cleaned with acetone and ethanol for 15 min, then washed with deionized water and blow-dried, followed by drying on a heating plate at 150° C. for 10 min, and then subjected to ultraviolet light (UV) irradiation for 20 min to increase the ITO work function.
Step 2: PEDOT:PSS was spin-coated at a speed of 4000 rpm for 30 s, and then heated on a heating plate at 150° C. for 20 min to obtain a hole injection layer with a thickness of 20 nm.
Step 3: TFB (concentration: 8 mg/mL) was spin-coated on the hole injection layer in an inert atmosphere at a speed of 3000 rpm for 30 s, and then heated on a heating plate at 120° C. for 20 min to obtain a hole transport layer with a thickness of 25 nm.
Step 4: the composite material 1 in a gel state was heated to 60° C. to transform the composite material 1 into a liquid state. The composite material 1 in the liquid state was spin-coated onto the hole transport layer, cooled to room temperature, and vacuum dried for 30 minutes to obtain a light-emitting layer with a thickness of 20 nm.
Step 5: a ZnO solution was spin-coated on the light-emitting layer at 4000 rpm for 30 s, followed by drying, to obtain an electron transport layer.
Step 6: Ag was evaporated on the electron transport layer by thermal evaporation at a vacuum degree no more than 3×10−4 Pa to obtain a cathode with a thickness of 100 nm.

### DEVICE EXAMPLE 2

This device example is similar to Device Example 1 except that the composite material 2 was used in step 4.

### DEVICE EXAMPLE 3

This device example is similar to Device Example 1 except that the composite material 3 was used in step 4.

### DEVICE EXAMPLE 4

This device example is similar to Device Example 1 except that the composite material 4 was used in step 4.

### DEVICE EXAMPLE 5

This device example is similar to Device Example 1 except that the composite material 5 was used in step 4.

### DEVICE EXAMPLE 6

This device example is similar to Device Example 1 except that the composite material 8 was used in step 4.

### DEVICE EXAMPLE 7

This device example is similar to Device Example 1 except that the composite material 9 was used in step 4.

### DEVICE EXAMPLE 8

This device example is similar to Device Example 1 except that the composite material 1 in the gel state used in step 4 was placed at room temperature for 3 days before being used.

### DEVICE COMPARATIVE EXAMPLE 1

This device example is similar to Device Example 1 except that the gel-like composite material 10 was used in step 4.

### DEVICE COMPARATIVE EXAMPLE 2

This device example is similar to Device Example 1 except that the gel-like composite material 11 was used in step 4.

### DEVICE COMPARATIVE EXAMPLE 3

This device example is similar to Device Example 1 except that the prepared composite material 1 was not used in step 4, and a solution having green quantum dots CdZnSe/ZnSe/ZnS and chlorobenzene was directly spin-coated on the hole transport layer, followed by vacuum drying for 30 min, to obtain a light-emitting layer with a thickness of 20 nm.

### DEVICE COMPARATIVE EXAMPLE 4

This device example is similar to Device Example 1 except that the composite material 6 was used in step 4.

### DEVICE COMPARATIVE EXAMPLE 5

This Device Example is essentially the same as Device Example 1, except that the composite material 7 was used in step 4.

### EXPERIMENTAL EXAMPLE

Tests were conducted on quantum dot light-emitting diodes of Device Examples 1-10 and Comparative Device Examples 1-3, specifically including current efficiency (C.E.) and lifetime (T95-1000 nit), with the data shown in Table 1. T95-1000 nit refers to the time it takes for the brightness of the device to decay from 100% to 95% at a brightness of 1000 nits.

TABLE 1

| items | C.E. (cd/A) | T95-1000 nit (h) |
|---|---|---|
| Device Example 1 | 110 | 10239 |
| Device Example 2 | 100 | 10012 |
| Device Example 3 | 52 | 2006 |
| Device Example 4 | 106 | 10145 |
| Device Example 5 | 102 | 10171 |
| Device Example 6 | 105 | 10146 |
| Device Example 7 | 106 | 10212 |
| Device Example 8 | 105 | 10189 |
| Comparative Device Example 1 | 43 | 1564 |
| Comparative Device Example 2 | 46 | 1653 |
| Comparative Device Example 3 | 82 | 8561 |
| Comparative Device Example 4 | 54 | 1986 |

As shown in Table 1, compared to Comparative Device Example 3, which uses a conventional quantum dot solution to prepare the light-emitting layer, Device Examples 1-8 exhibit better current efficiency (C.E.) and lifetime (T95-1000 nit), indicating that the use of the composite material containing quantum dots provided herein for preparing the quantum dot light-emitting layer enhances the luminous efficiency and lifespan of the light-emitting devices.

From Device Examples 1-3 and Comparative Device Examples 1 and 3, it may be observed that when the concentration of P-PPV in the composite material is greater than or equal to 2 mg/ml, the corresponding light-emitting devices exhibit better current efficiency (C.E.) and lifetime (T95-1000 nit) compared to Comparative Device Example 3, and when the concentration of P-PPV is 2 mg/ml to 3 mg/ml, there is a significant improvement in the current efficiency (C.E.) and lifetime (T95-1000 nit) of the light-emitting devices, possibly because at lower concentrations of P-PPV, the composite material struggles to form a gel-like state.

As may be seen from Device Examples 1, 4-5 and Device Comparative Examples 4-5, when the concentration of quantum dots in the composite material is 10 mg/ml and 40 mg/ml, the corresponding light-emitting devices have a certain degree of reduction in current efficiency C.E. and lifetime T95-1000 nit compared with Device Comparative Example 3. It may be due to the lower concentration of quantum dots (10 mg/ml), the content of quantum dots in the formed light-emitting layer is small, resulting in lower light-emitting efficiency and lifetime; and when the concentration of quantum dots is higher (40 mg/ml), the quantum dots cannot be uniformly dispersed in the composite material, and agglomeration occurs, resulting in uneven content of quantum dots in the formed light-emitting layer, resulting in reduced light-emitting efficiency and lifetime of the light-emitting device.

Compared with Device Example 1 which directly uses the composite material 1 prepared, the composite material 1 used in Device Example 1 is placed for 3 days before being used as a light-emitting layer, and the corresponding quantum dot light-emitting diode still has good current efficiency C.E. and lifetime T95-1000 nit, indicating that the composite material provided by the present disclosure may improve the dispersity of quantum dots, and the composite material still has good dispersion uniformity after long-term storage.

A composite material and a preparation method thereof, and a preparation method of a light-emitting device provided by the embodiments of the present disclosure are described in detail above, and the principles and the implementation manners of the present disclosure are described by using specific examples in the present text, and the above description of the embodiments is only used to help understand the method and the core idea of the present disclosure; meanwhile, for those skilled in the art, the specific implementation manners and the application range may be changed according to the idea of the present disclosure, and the above description of the present specification should not be understood as the limitation of the present disclosure.

1. A composite material comprising a nanoparticle, a temperature-responsive polymer and a solvent, wherein the temperature-responsive polymer has a first gelation critical temperature.

2. The composite material according to claim 1, wherein the composite material consists of the nanoparticle, the temperature-responsive polymer and the solvent.

3. The composite material according to claim 1, wherein
when a temperature is below the first gelation critical temperature, the temperature-responsive polymer cross-links with the solvent to form a network structure to cause the composite material to form a gel state.

4. The composite material according to claim 1, wherein when a temperature is above the first gelation critical temperature, the composite material is in a liquid state, and
the nanoparticle is selected from a quantum dot.

5. The composite material according to claim 4, wherein the temperature-responsive polymer is selected from one or more of poly(p-phenylenevinylene) and derivatives thereof,
the solvent comprises a first solvent selected from limonene;
the temperature-responsive polymer has a peak wavelength of 450 nm to 490 nm and the quantum dot has a peak wavelength of 450 nm to 490 nm; or the temperature-responsive polymer has a peak wavelength of 500 nm to 560 nm and the quantum dot has a peak wavelength of 500 nm to 560 nm; or the temperature-responsive polymer has a peak wavelength of 580 nm to 700 nm and the quantum dot has a peak wavelength of 580 nm to 700 nm.

6. The composite material according to claim 4, wherein an average particle size of the quantum dot is 4-6 nm;
the quantum dot is selected from one or more of a single-structure quantum dot, a core-shell structure quantum dot, and a perovskite semiconductor material, the single-structure quantum dot is selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and the group I-III-VI compound is selected from one or more of CuInS₂, CuInSe₂, and AgInS₂, a core of the core-shell structure quantum dot is selected from any one of the single-structure quantum dots, and a shell material of the core-shell structure quantum dot is selected from one or more of CdS, CdTe, CdSeTe, CdZnSe, CdZnS, CdSeS, ZnSe, ZnSeS, and ZnS, the perovskite semiconductor material is selected from a doped or non-doped inorganic perovskite semiconductor or an organic-inorganic hybrid perovskite semiconductor, a general structure of the inorganic perovskite semiconductor is AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻; a general structure of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n is 2 or more, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻.

7. The composite material according to claim 5, wherein a mass percentage of the first solvent in the solvent is 70% to 100%;
the solvent further comprises a second solvent selected from one or more of chlorobenzene and chloroform.

8. The composite material according to claim 7, wherein the temperature-responsive polymer is selected from one or more of PPV, P-PPV, CN-PPV, and DP-PPV;
a concentration of the temperature-responsive polymer in the composite material is 2 mg/mL to 3 mg/mL.

9. The composite material according to claim 7, wherein
a concentration of the nanoparticle in the composite material is 20 mg/mL to 30 mg/mL;
the quantum dot has a peak wavelength of 500 nm to 560 nm;
the first gelation critical temperature ranges from 25° C. to 35° C.

10. A method of preparing a composite material, comprising:
providing a nanoparticle, a temperature-responsive polymer, and a solvent, wherein the temperature-responsive polymer has a first gelation critical temperature;
mixing the nanoparticle, the temperature-responsive polymer, and the solvent to obtain the composite material.

11. The method according to claim 10, wherein:
the step of mixing the nanoparticle, the temperature-responsive polymer, and the solvent comprises:
mixing the nanoparticle, the temperature-responsive polymer, and the solvent at a first temperature to obtain the composite material, wherein the first temperature is greater than the first gelation critical temperature;
the nanoparticle is selected from a quantum dot.

12. The method according to claim 11, wherein:
the temperature-responsive polymer is selected from one or more of poly(p-phenylene vinylene) and derivatives thereof,
the solvent comprises a first solvent selected from limonene;
the first gelation critical temperature is greater than or equal to room temperature;
the temperature-responsive polymer has a peak wavelength of 450 nm to 490 nm and the quantum dot has a peak wavelength of 450 nm to 490 nm; or the temperature-responsive polymer has a peak wavelength of 500 nm to 560 nm and the quantum dot has a peak wavelength of 500 nm to 560 nm; or the temperature-responsive polymer has a peak wavelength of 580 nm to 700 nm and the quantum dot has a peak wavelength of 580 nm to 700 nm.

13. The method according to claim 12, wherein:
the quantum dot is selected from one or more of a single-structure quantum dot, a core-shell structure quantum dot, and a perovskite semiconductor material, the single-structure quantum dot is selected from one or more of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and the group I-III-VI compound is selected from one or more of CuInS₂, CuInSe₂, and AgInS₂, a core of the core-shell structure quantum dot is selected from any one of the single-structure quantum dots, and a shell material of the core-shell structure quantum dot is selected from one or more of CdS, CdTe, CdSeTe, CdZnSe, CdZnS, CdSeS, ZnSe, ZnSeS, and ZnS, the perovskite semiconductor material is selected from a doped or non-doped inorganic perovskite semiconductor or an organic-inorganic hybrid perovskite semiconductor, a general structure of the inorganic perovskite semiconductor is AMX₃, wherein A is a Cs⁺ ion, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻; a general structure of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n is 2 or more, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halide anion selected from one or more of Cl⁻, Br⁻, and I⁻.

14. The method according to claim 12, wherein,
the temperature-responsive polymer is selected from one or more of PPV, P-PPV, CN-PPV, and DP-PPV;
a concentration of the temperature-responsive polymer in the composite material is 2 mg/mL to 3 mg/mL;
a concentration of the nanoparticle in the composite material is 20 mg/mL to 30 mg/mL.

15. The method according to claim 12, wherein the solvent further comprises a second solvent selected from one or more of chlorobenzene and chloroform;
a mass percentage of the limonene in the solvent is 70% to 100%;
the quantum dot has a peak wavelength of 500 nm to 560 nm.

16. The method according to claim 14, wherein the temperature-responsive polymer is selected from P-PPV, and wherein the first gelation critical temperature ranges from 25° C. to 35° C.;
the first temperature ranges from 40° C. to 100° C.

17. A method of preparing a light-emitting device, comprising:
providing a first electrode and a composite material,
disposing the composite material on the first electrode to form a functional layer;
forming a second electrode on the functional layer;
wherein the composite material comprises a nanoparticle, a temperature-responsive polymer and a solvent, wherein the temperature-responsive polymer has a first gelation critical temperature.

18. The method according to claim 17, wherein the step of disposing the composite material on the first electrode comprises:
disposing the composite material in a liquid state on the first electrode at a temperature of a second temperature, wherein the second temperature is greater than the first gelation critical temperature and the composite material is in a liquid state; then, reducing the temperature to less than the first gelation critical temperature to cause the composite material disposed on the first electrode to transition from the liquid state to a gel state;
after the step of disposing the composite material on the first electrode, the method further comprises:
a drying process to remove a solvent from the composite material to form the functional layer.

19. The method according to claim 18, wherein,
the second temperature is 40° C. to 100° C.;
the drying process has a pressure of 0.1 Pa to 1 Pa, and a temperature of 20° C. to 40° C.;
the functional layer is selected from one or more of an electron functional layer, a light-emitting layer, and a hole functional layer.

20. The method according to claim 18, wherein,
the first electrode and the second electrode are independently selected from a metal electrode, a carbon electrode, a doped or undoped metal oxide electrode, and a composite electrode; wherein a material of the metal electrode is selected from one or more of Al, Ag, Cu, Mo, Au, Ba, Ca, and Mg; a material of the carbon electrode is selected from one or more of graphite, carbon nanotubes, graphene, and carbon fibers; a material of the doped or undoped metal oxide electrode is selected from one or more of ITO, FTO, ATO, AZO, GZO, IZO, MZO, and AMO; and a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS.
